(19) United States
(12) Patent Application Publication
(10) Pub. No.: US 2025/0203943 A1
(43) Pub. Date: Jun. 19, 2025

(54) SEMICONDUCTOR DEVICE INCLUDING OXIDE SEMICONDUCTOR

(71) Applicant: SK hynix Inc., Gyeonggi-do (KR)

(72) Inventor: Dong Jin KO, Gyeonggi-do (KR)

(21) Appl. No.: 18/762,645

(22) Filed: Jul. 3, 2024

(30) Foreign Application Priority Data
Dec. 15, 2023 (KR) 10-2023-0183305

(51) Int. Cl. H01L 29/786; H01L 29/417

(52) U.S. Cl. CPC H10D 30/6755; H10D 30/6729

(57) ABSTRACT

A semiconductor device includes a gate electrode layer; a control electrode layer; an oxide semiconductor layer disposed between the gate electrode layer and the control electrode layer; a gate dielectric layer disposed between the gate electrode layer and the oxide semiconductor layer; a reservoir layer disposed between the oxide semiconductor layer; and a solid-state electrolyte layer disposed between the oxide semiconductor layer and the reservoir layer.

### CROSS-REFERENCE TO RELATED APPLICATIONS

The present application claims priority under 35 U.S.C 119 (a) to Korean Patent Application No. 10-2023-0183305, filed on Dec. 15, 2023, which is incorporated herein by reference in its entirety.

### BACKGROUND

### 1. Field

Various embodiments of the present disclosure relate to a semiconductor technology, and more particularly, to a semiconductor device including an oxide semiconductor.

### 2. Description of the Related Art

Conventionally, amorphous silicon or polysilicon was mainly used as a semiconductor layer in a semiconductor device, for example, as a channel for a transistor. Amorphous silicon has the advantage of being relatively inexpensive and capable of securing uniform device characteristics through a simple process, but has the disadvantage of low carrier mobility. Polysilicon may be obtained by crystallizing amorphous silicon and may have relatively high carrier mobility. However, when forming polysilicon, a recrystallization process is required and it is difficult to secure uniform device characteristics.

### SUMMARY

Embodiments of the present disclosure are directed to a semiconductor device capable of improving the characteristics of a transistor.

In accordance with an embodiment of the present disclosure, a semiconductor device includes a gate electrode layer; a control electrode layer; an oxide semiconductor layer disposed between the gate electrode layer and the control electrode layer; a gate dielectric layer disposed between the gate electrode layer and the oxide semiconductor layer; a reservoir layer disposed between the oxide semiconductor layer and the control electrode layer, the reservoir layer being configured to supply or absorb oxygen ions; and a solid-state electrolyte layer disposed between the oxide semiconductor layer and the reservoir layer, the solid-state electrolyte layer being configured to migrate the oxygen ions between the reservoir layer and the oxide semiconductor layer.

In accordance with another embodiment of the present disclosure, a semiconductor device includes a gate electrode layer; a control electrode layer; an oxide semiconductor layer disposed between the gate electrode layer and the control electrode layer; a gate dielectric layer disposed between the gate electrode layer and the oxide semiconductor layer; a reservoir layer disposed between the oxide semiconductor layer and the control electrode layer, the reservoir layer being configured to supply or absorb hydrogen ions; and a solid-state electrolyte layer disposed between the oxide semiconductor layer and the reservoir layer, the solid-state electrolyte layer being configured to migrate the hydrogen ions between the reservoir layer and the oxide semiconductor layer.

### BRIEF DESCRIPTION OF THE DRAWINGS

FIG. 1 is a cross-sectional view illustrating a semiconductor device in accordance with an embodiment of the present disclosure.

FIGS. 2A to 2C are cross-sectional views illustrating diverse methods for operating the semiconductor device shown in FIG. 1 in accordance with another embodiment of the present disclosure.

FIG. 3A is a cross-sectional view illustrating a semiconductor device in accordance with another embodiment of the present disclosure.

FIG. 3B is a cross-sectional view illustrating a semiconductor device in accordance with another embodiment of the present disclosure.

FIG. 4 is a cross-sectional view illustrating a semiconductor device in accordance with another embodiment of the present disclosure.

### DETAILED DESCRIPTION

Various embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the diverse embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

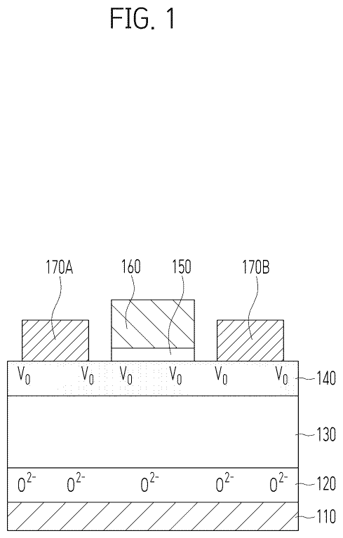

FIG. 1 is a cross-sectional view illustrating a semiconductor device in accordance with an embodiment of the present disclosure.

Referring to FIG. 1, the semiconductor device in accordance with an embodiment of the present disclosure may include a control electrode layer 110, a reservoir layer 120 disposed over the control electrode layer 110, a solid-state electrolyte layer 130 disposed over the reservoir layer 120, and an oxide semiconductor layer 140 disposed over the solid-state electrolyte layer 130. Further, the semiconductor device may include a gate dielectric layer 150, a gate electrode layer 160, a source electrode layer 170A and a drain electrode layer 170B, which are disposed over the oxide semiconductor layer 140. The gate dielectric layer 150 may be interposed between the oxide semiconductor layer 140 (e.g., a portion of the oxide semiconductor layer 140), and the gate electrode layer 160. The source electrode layer 170A and the drain electrode layer 170B may be respectively adjacent to both sides of the gate electrode layer 160 over the oxide semiconductor layer 140 (e.g., portions of the oxide semiconductor layer 140).

Here, the oxide semiconductor layer 140, the gate dielectric layer 150, and the gate electrode layer 160 may form a transistor. The gate electrode layer 160 may correspond to a gate of the transistor. The oxide semiconductor layer 140 may provide a source region of the transistor, a drain region of the transistor, and a channel region of the transistor between the source region and the drain region. The region of the oxide semiconductor layer 140 that is vertically overlaps with or next to (i.e., electrically connected to) the gate electrode layer 160 through the gate dielectric layer 150 may function as the channel region of the transistor, and the regions adjacent to both sides of the channel region of the transistor of the oxide semiconductor layer 140 may function as the source region and the drain region. The gate dielectric layer 150 may be interposed between the gate electrode layer 160 and the oxide semiconductor layer 140 to physically insulate them from each other. The gate electrode layer 160 may include diverse conductive materials such as metals, alloys, metal compounds, and combinations thereof, and may have a single-layer structure or a multi-layer structure. In one embodiment, the gate dielectric layer 150 may include diverse dielectric materials such as silicon oxide, silicon nitride, silicon oxynitride, aluminum oxide, and the like. In another embodiment, the gate dielectric layer 150 may include a high-k material having a higher dielectric constant than silicon oxide, such as zirconium oxide, hafnium oxide, lanthanum oxide, tantalum oxide, or titanium oxide. The oxide semiconductor layer 140 may include an oxide of at least one metal selected from among group-12, group-13, and group-14 metals, such as Zinc (Zn), indium (In), gallium (Ga), tin (Sn), cadmium (Cd), germanium (Ge), and hafnium (Hf). For example, the oxide semiconductor layer 140 may include In—Sn—Ga—Zn oxide, In—Ga—Zn oxide, In—Sn—Zn oxide, In—Al—Zn oxide, Sn—Ga—Zn oxide, Al—Ga—Zn oxide, Sn—Al—Zn oxide, In—Zn oxide, Sn—Zn oxide, Al—Zn oxide, Zn—Mg oxide, Sn—Mg oxide, In—Mg oxide, In—Ga oxide, and the like.

The reservoir layer 120 may include a material which is electrically conductive and contains oxygen, such as an oxide. The reservoir layer 120 may discharge and/or supply oxygen ions, i.e., O²⁻ ions, to the outside according to the applied voltage, or may react with oxygen ions introduced from the outside to absorb the oxygen ions. According to this embodiment of the present disclosure, the reservoir layer 120 may supply oxygen ions to the oxide semiconductor layer 140 or may absorb oxygen ions introduced from the oxide semiconductor layer 140. The reservoir layer 120 may include diverse oxides, such as titanium oxide, tungsten oxide, lanthanum strontium manganese oxide (LSMO), ruthenium oxide and the like. Also, the reservoir layer 120 may include oxygen in a content that satisfies or exceeds the stoichiometric ratio in order to facilitate the release and/or supply of the oxygen ions.

The solid-state electrolyte layer 130 may include a material which is an electrical insulator and capable of migrating oxygen ions. According to this embodiment of the present disclosure, oxygen ions may be able to migrate between the reservoir layer 120 and the oxide semiconductor layer 140 through the solid-state electrolyte layer 130. The solid-state electrolyte layer 130 may include, for example, yttria stabilized zirconia (YSZ), gadolinium oxide, silicon oxide, and the like.

The control electrode layer 110 may be electrically connected to the reservoir layer 120 and may correspond to a terminal for applying a required voltage to the reservoir layer 120. The control electrode layer 110 may include diverse conductive materials, such as metals, alloys, metal compounds, or combinations thereof, and may have a single-layer structure or a multi-layer structure.

The source electrode layer 170A may be electrically connected to the source region of the transistor, and the drain electrode layer 170B may be electrically connected to the drain region of the transistor. According to this embodiment of the present disclosure, the source electrode layer 170A may be adjacent to the left side of the gate electrode layer 160 and may directly contact the oxide semiconductor layer 140, and the drain electrode layer 170B may be adjacent to the right side of the gate electrode layer 160 and may directly contact the oxide semiconductor layer 140. However, the embodiments of the present disclosure are not limited to it, and the left and right positions of the source electrode layer 170A and the drain electrode layer 170B may be switched. Also, another conductive layer may be further interposed between the source electrode layer 170A and the oxide semiconductor layer 140 and/or between the drain electrode layer 170B and the oxide semiconductor layer 140. Each of the source electrode layer 170A and the drain electrode layer 170B may include diverse conductive materials, such as metals, alloys, metal compounds, or combinations thereof, and may have a single-layer structure or a multi-layer structure.

In the cross-section, the width of the oxide semiconductor layer 140 may have a value which is greater than the sum of the width of the gate electrode layer 160, the width of the source electrode layer 170A, and the width of the drain electrode layer 170B. The width of the solid-state electrolyte layer 130, the width of the reservoir layer 120, and the width of the control electrode layer 110 may be substantially the same as the width of the oxide semiconductor layer 140. However, the embodiments of the present disclosure are not limited to it, and the width of the solid-state electrolyte layer 130, the width of the reservoir layer 120, and the width of the control electrode layer 110 may be controlled in diverse ways.

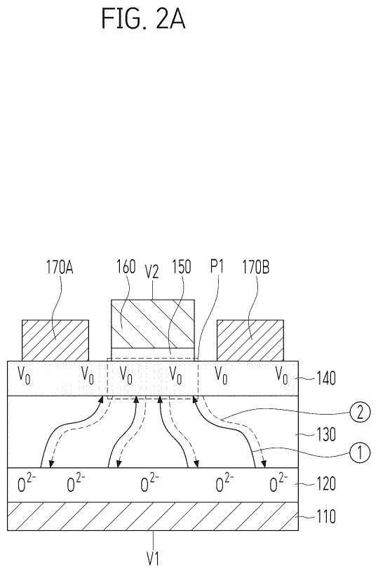

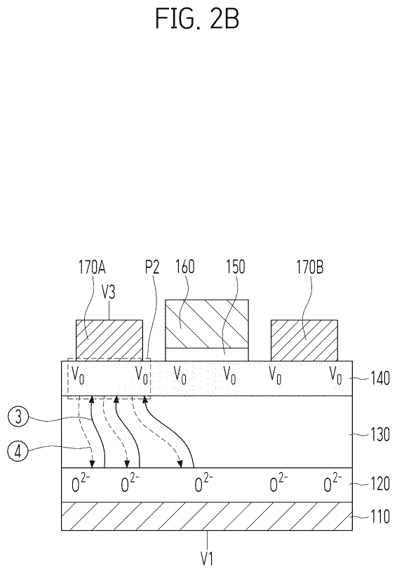

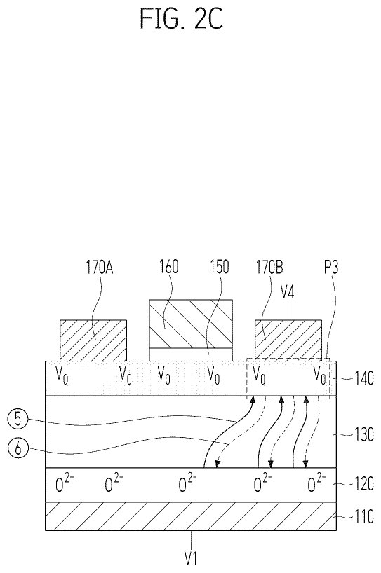

In the semiconductor device of this embodiment of the present disclosure, it is possible to control the content and/or density of oxygen vacancies (see a reference symbol V_{O}) formed in the oxide semiconductor layer 140. To be more specific, according to the voltage applied to the control electrode layer 110, oxygen ions from the reservoir layer 120 may be supplied to the oxide semiconductor layer 140 through the solid-state electrolyte layer 130, or the oxygen ions supplied to the oxide semiconductor layer 140 may return to the reservoir layer 120 through the solid-state electrolyte layer 130. When the oxygen ions migrate from the reservoir layer 120 to the oxide semiconductor layer 140, the oxygen vacancies in the oxide semiconductor layer 140 may be decreased. Conversely, when the oxygen ions migrate from the oxide semiconductor layer 140 to the reservoir layer 120, the oxygen vacancies in the oxide semiconductor layer 140 may be increased. Furthermore, according to the voltage applied to each of the gate electrode layer 160, the source electrode layer 170A, and the drain electrode layer 170B, the content and/or density of the oxygen vacancies may be controlled for each region of the oxide semiconductor layer 140. It is possible to independently reduce or increase the oxygen vacancies in each of the source region, channel region, and drain region of the oxide semiconductor layer 140. This will be described in detail below by referring to FIGS. 2A to 2C.

Conventional semiconductor devices using an oxide semiconductor as a channel and source/drain of a transistor hardly control the content of the oxygen vacancies in the oxide semiconductor, causing a problem of deteriorating the characteristics of a transistor. For example, when there are too many oxygen vacancies in the oxide semiconductor during the process of fabricating a transistor, the conductivity of the channel of the transistor may be increased, that is, the threshold voltage of the transistor may be decreased, which makes it difficult to turn off the transistor. To solve this problem, a method of performing an oxygen annealing process to remove the oxygen vacancies in the oxide semiconductor may be considered. However, this method may cause other problems, such as a problem of requiring a high temperature process and a problem of reducing the conductivity of the other constituent elements of the semiconductor device, e.g., a metal layer, by oxidizing the constituent elements. Also, performing an oxygen annealing process may increase the content and/or density of oxygen in the source/drain region as well as the channel of the transistor, which may cause another problem of increasing the contact resistance between the oxygen semiconductor and the source/drain electrodes by promoting the formation of a dielectric oxide between the oxide semiconductor and the source/drain electrodes.

On the other hand, according to the semiconductor device in accordance with this embodiment of the present disclosure, the reservoir layer 120 capable of supplying or absorbing oxygen ions and the solid-state electrolyte layer 130 capable of migrating oxygen ions may be additionally disposed to control the content of the oxygen vacancies in the oxide semiconductor layer 140 without an oxygen annealing process. Furthermore, by adjusting the voltage applied to each of the control electrode layer 110, the gate electrode layer 160, the source electrode layer 170A, and the drain electrode layer 170B to independently control the content of the oxygen vacancies for each region of the oxide semiconductor layer 140. As a result, it is possible to improve the characteristics of the transistor without diverse problems that may occur during the fabrication process, such as oxygen annealing.

FIGS. 2A to 2C are cross-sectional views illustrating diverse methods for operating the semiconductor device shown in FIG. 1 in accordance with another embodiment of the present disclosure. FIG. 2A illustrates a method for controlling the content of the oxygen vacancies in the channel region of the oxide semiconductor layer 140. FIG. 2B illustrates a method for controlling the content of the oxygen vacancies in the source region of the oxide semiconductor layer 140. FIG. 2C illustrates a method for controlling the content of the oxygen vacancies in the drain region of the oxide semiconductor layer 140.

Referring to FIG. 2A, migration of oxygen ions may occur between the reservoir layer 120 and the oxide semiconductor layer 140. Particularly, migration of oxygen ions may occur in the first region P1 of the oxide semiconductor layer 140, by applying a first voltage V1 to the control electrode layer 110 and applying a second voltage V2 to the gate electrode layer 160. The first region P1 may overlap with or be next to (i.e., electrically connected to) the gate electrode layer 160 through the gate dielectric layer 150 and may correspond to the channel region of the transistor. Although not illustrated, the source electrode layer 170A and the drain electrode layer 170B may be in a floating state, or a voltage which is substantially the same as the first voltage V1 may be applied to the source electrode layer 170A and the drain electrode layer 170B. In this case, migration of oxygen ions may not substantially occur between the reservoir layer 120 and the remaining region of the oxide semiconductor layer 140 except for the first region P1, that is, the source/drain region.

For example, when a relatively low voltage is applied to the control electrode layer 110 compared to a voltage applied to the gate electrode layer 160, a first case where the oxygen ions of the reservoir layer 120 migrate to the oxide semiconductor layer 140, particularly, the first region P1 of the oxide semiconductor layer 140, through the solid-state electrolyte layer 130 may occur (see arrow (1)). For example, applying a relatively low voltage to the control electrode layer 110 compared to a voltage applied to the gate electrode layer 160 may include when the first voltage V1 is a predetermined negative voltage and the second voltage V2 is a ground voltage, or when the first voltage V1 is the ground voltage and the second voltage V2 is a predetermined positive voltage. In the first case, the oxygen vacancies in the first region P1 of the oxide semiconductor layer 140 may be decreased. This may mean an increase in the threshold voltage of the transistor.

Conversely, when a relatively high voltage is applied to the control electrode layer 110 compared to a voltage applied to the gate electrode layer 160, a second case where the oxygen ions of the oxide semiconductor layer 140, particularly, the first region P1 of the oxide semiconductor layer 140, migrate to the reservoir layer 120 through the solid-state electrolyte layer 130 may occur (see arrow 2). Here, the oxygen ions in the first region P1 of the oxide semiconductor layer 140 may be oxygen ions that are supplied according to the first case. For example, applying a relatively high voltage to the control electrode layer 110 compared to a voltage applied to the gate electrode layer 160 may include when the first voltage V1 is a predetermined positive voltage and the second voltage V2 is the ground voltage, or when the first voltage V1 is the ground voltage and the second voltage V2 is a predetermined negative voltage. In the second case, the oxygen vacancies in the first region P1 may be increased again. This may mean a decrease in the threshold voltage of the transistor.

Referring to FIG. 2B, by applying the first voltage V1 to the control electrode layer 110 and applying a third voltage V3 to the source electrode layer 170A, migration of the oxygen ions between the reservoir layer 120 and the oxide semiconductor layer 140, particularly, the second region P2 of the oxide semiconductor layer 140, may occur. The second region P2 may be adjacent to a first side of the gate electrode layer 160 so as to vertically overlap with or to be next to (i.e., electrically connected to) the source electrode layer 170A, and the second region P2 may correspond to the source region of the transistor. Although not illustrated, the gate electrode layer 160 and the drain electrode layer 170B may be in a floating state, or a voltage which is substantially the same as the first voltage V1 may be applied to the gate electrode layer 160 and the drain electrode layer 170B. In this case, migration of the oxygen ions between the reservoir layer 120 and the remaining region of the oxide semiconductor layer 140 except for the second region P2, that is, the channel region and the drain region, may not substantially occur.

For example, when a relatively low voltage is applied to the control electrode layer 110 compared to a voltage applied to the source electrode layer 170A, a third case where the oxygen ions of the reservoir layer 120 migrate to the oxide semiconductor layer 140, particularly, the second region P2 of the oxide semiconductor layer 140, through the solid-state electrolyte layer 130 may occur (see arrow (3). For example, applying a relatively low voltage to the control electrode layer 110 compared to a voltage applied to the source electrode layer 170A may include when the first voltage V1 is a predetermined negative voltage and the third voltage V3 is the ground voltage, or when the first voltage V1 is the ground voltage and the third voltage V3 is a predetermined positive voltage. In the third case, the oxygen vacancies in the second region P2 of the oxide semiconductor layer 140 may be decreased. In this case, the possibility of generating a dielectric oxide between the source electrode layer 170A and the oxide semiconductor layer 140 may be increased, thereby increasing the contact resistance between the source electrode layer 170A and the oxide semiconductor layer 140.

Conversely, when a relatively high voltage is applied to the control electrode layer 110 compared to a voltage applied to the source electrode layer 170A, a fourth case where the oxygen ions of the oxide semiconductor layer 140, particularly, the second region P2 of the oxide semiconductor layer 140, migrate to the reservoir layer 120 through the solid-state electrolyte layer 130 (see arrow 4). Here, the oxygen ions of the second region P2 of the oxide semiconductor layer 140 may be oxygen ions that are supplied according to the third case. For example, applying a relatively high voltage to the control electrode layer 110 compared to a voltage applied to the source electrode layer 170A may include when the first voltage V1 is a predetermined positive voltage and the third voltage V3 is the ground voltage, or when the first voltage V1 is the ground voltage and the third voltage V3 is a predetermined negative voltage. In the fourth case, the oxygen vacancies of the second region P2 may be increased again. In this case, the possibility of generating a dielectric oxide between the source electrode layer 170A and the oxide semiconductor layer 140 may be decreased, thereby reducing the contact resistance between the source electrode layer 170A and the oxide semiconductor layer 140.

Referring to FIG. 2C, migration of the oxygen ions between the reservoir layer 120 and the oxide semiconductor layer 140, particularly, a third region P3 of the oxide semiconductor layer 140, may occur by applying the first voltage V1 to the control electrode layer 110 and applying a fourth voltage V4 to the drain electrode layer 170B. The third region P3 may be adjacent to a second side of the gate electrode layer 160 so as to be next to (i.e., electrically connected to) the drain electrode layer 170B, and the third region P3 may correspond to the drain region of the transistor. Although not illustrated, the gate electrode layer 160 and the source electrode layer 170A may be in a floating state, or a voltage which is substantially the same as the first voltage V1 may be applied to the gate electrode layer 160 and the source electrode layer 170A. In this case, migration of oxygen ions may not substantially occur between the reservoir layer 120 and the remaining region of the oxide semiconductor layer 140 except for the third region P3, that is, the channel region and the source region.

For example, when a relatively low voltage is applied to the control electrode layer 110 compared to a voltage applied to the drain electrode layer 170B, a fifth case where the oxygen ions of the reservoir layer 120 migrate to the oxide semiconductor layer 140, particularly, to the third region P3 of the oxide semiconductor layer 140, through the solid-state electrolyte layer 130 may occur (see arrow 5). For example, applying a relatively low voltage to the control electrode layer 110 compared to a voltage applied to the drain electrode layer 170B may include when the first voltage V1 is a predetermined negative voltage and the fourth voltage V4 is the ground voltage, or when the first voltage V1 is the ground voltage and the fourth voltage V4 is a predetermined positive voltage. In the fifth case, the oxygen vacancies in the third region P3 of the oxide semiconductor layer 140 may be decreased. In this case, the possibility of generating a dielectric oxide between the drain electrode layer 170B and the oxide semiconductor layer 140 may be increased, thereby increasing the contact resistance between the drain electrode layer 170B and the oxide semiconductor layer 140.

Conversely, when a relatively high voltage is applied to the control electrode layer 110 compared to a voltage applied to the drain electrode layer 170B, a sixth case where the oxygen ions in the oxide semiconductor layer 140, particularly, the third region P3 of the oxide semiconductor layer 140, migrate to the reservoir layer 120 through the solid-state electrolyte layer 130 may occur (see arrow 6). Here, the oxygen ions in the third region P3 of the oxide semiconductor layer 140 may be the oxygen ions that are supplied according to the fifth case. For example, applying a relatively high voltage to the control electrode layer 110 compared to a voltage applied to the drain electrode layer 170B may include when the first voltage V1 is a predetermined positive voltage and the fourth voltage V4 is the ground voltage, or when the first voltage V1 is the ground voltage and the fourth voltage V4 is a predetermined negative voltage. In the sixth case, the oxygen vacancies in the third region P3 may be increased again. In this case, the possibility of generating a dielectric oxide between the drain electrode layer 170B and the oxide semiconductor layer 140 may be decreased, thereby reducing the contact resistance between the drain electrode layer 170B and the oxide semiconductor layer 140.

At least one among the first to sixth cases described above may be performed as needed. For example, when the density of the oxygen vacancies in the channel region of the transistor is too high and a normally turn-on phenomenon occurs in which a transistor is not turned off easily, it may be required to supply oxygen ions to the channel region of the transistor. To this end, the first case may be performed. For example, when the density of the oxygen vacancies in the source/drain region of the transistor is too low and a dielectric oxide is formed between the source/drain region and the source/drain electrode, it may be required to recover the oxygen ions from the source/drain region of the transistor. To this end, at least one among the fourth case and the sixth case may be performed. However, the embodiments of the present disclosure are not limited to it, and one or more among the first to sixth cases may be diversely combined and used.

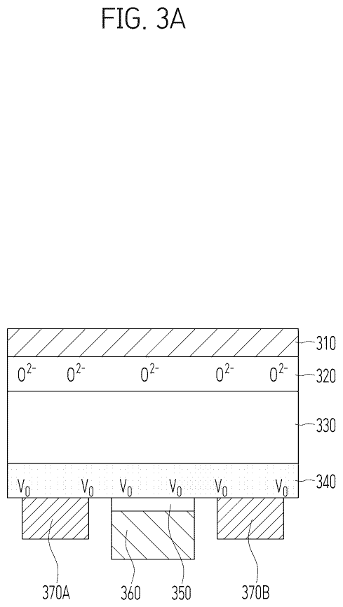

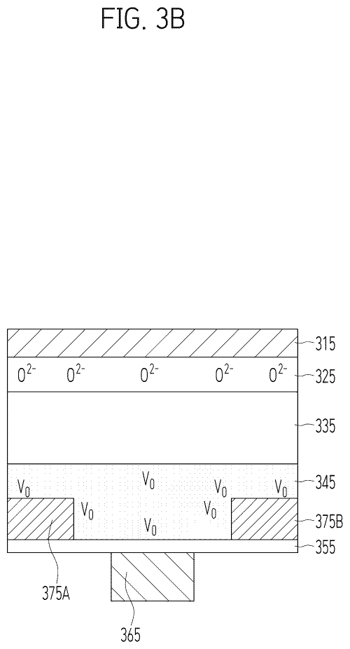

As described above, the above embodiment of the present disclosure describes a top gate structure in which the gate electrode layer 160 is disposed over the oxide semiconductor layer 140 with the gate dielectric layer 150 interposed therebetween. In this case, the solid-state electrolyte layer 130, the reservoir layer 120, and the control electrode layer 110 may be disposed below the oxide semiconductor layer 140. Also, the source electrode layer 170A and the drain electrode layer 170B may be disposed over the oxide semiconductor layer 140. However, the embodiments of the present disclosure are not limited to it, and it is possible to form a bottom gate structure in which the gate electrode layer is disposed below the oxide semiconductor layer with the gate dielectric layer interposed therebetween (see FIGS. 3A and 3B, which will be described later). Furthermore, the relative positions of the oxide semiconductor layer, the gate dielectric layer, the gate electrode layer, the solid-state electrolyte layer, the reservoir layer, and the control electrode layer may vary under the following conditions. The gate electrode layer and the control electrode layer may be spaced apart from each other in a predetermined direction, for example, a horizontal direction which is substantially parallel to the surface of the substrate (not shown) or a vertical direction which is substantially perpendicular to the surface of the substrate. In this predetermined direction, the oxide semiconductor layer may be disposed between the gate electrode layer and the control electrode layer, the gate dielectric layer may be disposed between the oxide semiconductor layer and the gate electrode layer, the reservoir layer may be disposed between the oxide semiconductor layer and the control electrode layer, and the solid-state electrolyte layer may be disposed between the oxide semiconductor layer and the reservoir layer. Also, when one side of the oxide semiconductor layer facing the gate electrode layer is called a first side and another side of the oxide semiconductor layer facing the solid-state electrolyte layer is called a second side, the source electrode layer and the drain electrode layer may be disposed to face the first side of the oxide semiconductor layer.

FIG. 3A is a cross-sectional view illustrating a semiconductor device in accordance with another embodiment of the present disclosure.

Referring to FIG. 3A, the semiconductor device in accordance with this embodiment of the present disclosure may include a control electrode layer 310, a reservoir layer 320 disposed below the control electrode layer 310, a solid-state electrolyte layer 330 disposed below the reservoir layer 320, and an oxide semiconductor layer 340 disposed below the solid-state electrolyte layer 330. Further, the semiconductor device may include a gate dielectric layer 350, a gate electrode layer 360, and a source electrode layer 370A and a drain electrode layer 370B, which are disposed below the oxide semiconductor layer 340. The gate dielectric layer 350 may be interposed between the oxide semiconductor layer 340 (e.g., a portion of the oxide semiconductor layer 340), and the gate electrode layer 360. The source electrode layer 370A and the drain electrode layer 370B may be adjacent to both sides of the gate electrode layer 360, respectively, below the oxide semiconductor layer 340 (e.g., portions of the oxide semiconductor layer 340).

Similarly to the above-described embodiment of the present disclosure in FIGS. 2A to 2C, the density of the oxygen vacancies of the oxide semiconductor layer 340 may be controlled by the migration of the oxygen ions between the reservoir layer 320 and the oxide semiconductor layer 340.

FIG. 3B is a cross-sectional view illustrating a semiconductor device in accordance with another embodiment of the present disclosure.

Referring to FIG. 3B, the semiconductor device in accordance with this embodiment of the present disclosure may include a control electrode layer 315, a reservoir layer 325 disposed below the control electrode layer 315, a solid-state electrolyte layer 335 disposed below the reservoir layer 325, and an oxide semiconductor layer 345 disposed below the solid-state electrolyte layer 335. Further, the semiconductor device may include a gate dielectric layer 355 disposed below the oxide semiconductor layer 345, and a gate electrode layer 365 disposed below the gate dielectric layer 355. The gate dielectric layer 355 may be interposed between the oxide semiconductor layer 345 and the gate electrode layer 365. For example, the gate electrode layer 365 may be disposed below a portion of the gate dielectric layer 355. Furthermore, the semiconductor device may include a source electrode layer 375A and a drain electrode layer 375B adjacent to both sides of the gate electrode layer 365, respectively, inside the oxide semiconductor layer 345.

Similarly to the above-described embodiment of the present disclosure, the density of the oxygen vacancies of the oxide semiconductor layer 345 may be controlled by the migration of the oxygen ions between the reservoir layer 325 and the oxide semiconductor layer 345.

The difference between the embodiments of FIGS. 3A and 3B lies in the positions of the source electrode layers 370A and 375A and the positions of the drain electrode layers 370B and 375B, and the shapes of the oxide semiconductor layers 340 and 345 according to the positions. In FIG. 3A, the top surfaces of the source electrode layer 370A and the drain electrode layer 370B may be disposed at substantially the same level as the top surface of the gate dielectric layer 350, and the bottom surface of the oxide semiconductor layer 340 may be disposed at a predetermined level while contacting the top surfaces of the source electrode layer 370A and the drain electrode layer 370B. On the other hand, in FIG. 3B, the top surfaces of the source electrode layer 375A and the drain electrode layer 375B may be disposed over the top surface of the gate dielectric layer 355, and the bottom surfaces of the source electrode layer 375A and the drain electrode layer 375B may be disposed at substantially the same level as the top surface of the gate dielectric layer 355. Also, the oxide semiconductor layer 345 may cover and contact the top surfaces of the source electrode layer 375A and the drain electrode layer 375B and at least a portion of the side walls of the source electrode layer 375A and the drain electrode layer 375B.

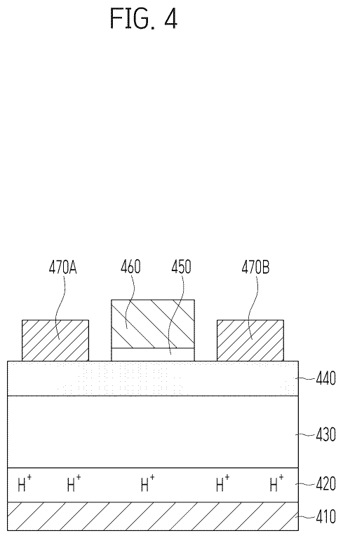

The above embodiments of the present disclosure describe the case where the reservoir layer includes a material capable of supplying oxygen ions or reacting with oxygen ions and the solid-state electrolyte layer includes a material capable of migrating oxygen ions. This is because the conductivity of the oxide semiconductor layer, that is, the threshold voltage of the transistor, is controlled by increasing or decreasing the oxygen vacancies in the oxide semiconductor layer. However, the embodiments of the present disclosure are not limited to it, and the threshold voltage of the transistor may be controlled by supplying hydrogen ions to the oxide semiconductor layer. This will be described below by referring to FIG. 4.

FIG. 4 is a cross-sectional view illustrating a semiconductor device in accordance with another embodiment of the present disclosure. The description will be made focusing on the differences from the above-described embodiments of the present disclosure.

Referring to FIG. 4, the semiconductor device in accordance with this embodiment of the present disclosure may include a control electrode layer 410, a reservoir layer 420 disposed over the control electrode layer 410, a solid-state electrolyte layer 430 disposed over the reservoir layer 420, and an oxide semiconductor layer 440 disposed over the solid-state electrolyte layer 430. Further, the semiconductor device may include a gate dielectric layer 450, a gate electrode layer 460, a source electrode layer 470A and a drain electrode layer 470B, which are disposed over the oxide semiconductor layer 440. The gate dielectric layer 450 may be interposed between the oxide semiconductor layer 440 (e.g., a portion of the oxide semiconductor layer 440), and the gate electrode layer 460. The source electrode layer 470A and the drain electrode layer 470B may be adjacent to both sides of the gate electrode layer 460, respectively, over the oxide semiconductor layer 440 (e.g., portions of the oxide semiconductor layer 440).

The reservoir layer 420 may include a material which is electrically conductive and contains hydrogen, such as a noble metal-containing material capable of storing hydrogen. The reservoir layer 420 may discharge and/or supply hydrogen ions, i.e., H+ ions, to the outside, or absorb hydrogen ions from the outside according to the applied voltage. According to this embodiment of the present disclosure, the reservoir layer 420 may supply hydrogen ions to the oxide semiconductor layer 440 or may absorb hydrogen ions from the oxide semiconductor layer 440. The reservoir layer 420 may include diverse noble metal-containing materials, such as palladium, platinum, ruthenium, and ruthenium oxide.

The solid-state electrolyte layer 430 may include a material that is electrically insulating and capable of migrating hydrogen ions. According to this embodiment of the present disclosure, hydrogen ions may be able to migrate between the reservoir layer 420 and the oxide semiconductor layer 440 through the solid-state electrolyte layer 430. The solid-state electrolyte layer 430 may include, for example, yttria stabilized zirconia (YSZ), gadolinium oxide, silicon oxide, or phosphosilicate glass (PSG).

The semiconductor device in accordance with the embodiment of the present disclosure may control the content and/or density of the hydrogen ions in the oxide semiconductor layer 440. To be more specific, according to the voltage applied to the control electrode layer 410, hydrogen ions may be supplied from the reservoir layer 420 to the oxide semiconductor layer 440 through the solid-state electrolyte layer 430, or the hydrogen ions supplied to the oxide semiconductor layer 440 may return to the reservoir layer 420 through the solid-state electrolyte layer 430. When the hydrogen ions migrate from the reservoir layer 420 to the oxide semiconductor layer 440, the content of hydrogen in the oxide semiconductor layer 440 may be increased. Since hydrogen functions as a donor in the oxide semiconductor layer 440, when the content of hydrogen in the oxide semiconductor layer 440 is increased, the conductivity of the oxide semiconductor layer 440 may be increased. That is, the threshold voltage of the transistor may be decreased. Conversely, when the hydrogen ions migrate from the oxide semiconductor layer 440 to the reservoir layer 420, the content of hydrogen in the oxide semiconductor layer 440 may be decreased, thereby reducing the conductivity of the oxide semiconductor layer 440. Namely, the threshold voltage of the transistor may be increased. Furthermore, the content and/or density of hydrogen may be controlled for each region of the oxide semiconductor layer 440 according to the voltage applied to each of the gate electrode layer 460, the source electrode layer 470A, and the drain electrode layer 470B. Hydrogen may be independently decreased or increased in each of the source region, the channel region, and the drain region of the oxide semiconductor layer 440. This method may be similar to what is described in FIGS. 2A to 2C. Unlike oxygen ions which are negative ions, hydrogen ions may be positive ions. Accordingly, when a relatively high voltage is applied to the control electrode layer 410 compared to a voltage applied to the gate electrode layer 460, the source electrode layer 470A, or the drain electrode layer 470B, hydrogen ions may migrate from the reservoir layer 420 to the oxide semiconductor layer 440. Also, when a relatively low voltage is applied to the control electrode layer 410 compared to a voltage applied to the gate electrode layer 460, the source electrode layer 470A, or the drain electrode layer 470B, hydrogen ions may migrate from the oxide semiconductor layer 440 to the reservoir layer 420.

The semiconductor device in accordance with this embodiment of the present disclosure may control the content of hydrogen in the oxide semiconductor layer 440 by disposing the reservoir layer 420 capable of supplying or absorbing hydrogen ions, and the solid-state electrolyte layer 430 capable of migrating hydrogen ions. Furthermore, the content of hydrogen may be independently controlled for each region of the oxide semiconductor layer 440 by controlling the voltage applied to each of the control electrode layer 410, the gate electrode layer 460, the source electrode layer 470A, and the drain electrode layer 470B. As a result, it is possible to improve the characteristics of the transistor.

According to embodiments of the present disclosure, a semiconductor device capable of improving the characteristics of a transistor may be provided.

While the present disclosure has been described with respect to the specific embodiments, it will be apparent to those skilled in the art that various changes and modifications may be made without departing from the spirit and scope of the disclosure as defined in the following claims. Furthermore, the embodiments may be combined to form additional embodiments.

What is claimed is:

1. A semiconductor device, comprising:
a gate electrode layer;
a control electrode layer;
an oxide semiconductor layer disposed between the gate electrode layer and the control electrode layer;
a gate dielectric layer disposed between the gate electrode layer and the oxide semiconductor layer;
a reservoir layer disposed between the oxide semiconductor layer and the control electrode layer; and
a solid-state electrolyte layer disposed between the oxide semiconductor layer and the reservoir layer.

2. The semiconductor device of claim 1, wherein:
the reservoir layer is configured to supply or receive oxygen ions, and
the solid-state electrolyte layer in configured to migrate the oxygen ions from or to the reservoir layer.

3. The semiconductor device of claim 2, wherein by applying a voltage to the control electrode layer, the oxygen ions migrate from the reservoir layer to the oxide semiconductor layer through the solid-state electrolyte layer, or migrate from the oxide semiconductor layer to the reservoir layer through the solid-state electrolyte layer.

4. The semiconductor device of claim 3,
wherein the gate electrode layer, the gate dielectric layer, and the oxide semiconductor layer form a transistor,
when the oxygen ions migrate from the reservoir layer to the oxide semiconductor layer, a threshold voltage of the transistor increases, and
when the oxygen ions migrate from the oxide semiconductor layer to the reservoir layer, a threshold voltage of the transistor decreases.

5. The semiconductor device of claim 2, wherein when a relatively low voltage is applied to the control electrode layer compared to a voltage applied to the gate electrode layer, the oxygen ions migrate from the reservoir layer to a first region of the oxide semiconductor layer through the solid-state electrolyte layer, and wherein the first region of the oxide semiconductor layer is next to the gate electrode layer through the gate dielectric layer.

6. The semiconductor device of claim 2, wherein when a relatively high voltage is applied to the control electrode layer compared to a voltage applied to the gate electrode layer, the oxygen ions migrate from a first region of the oxide semiconductor layer to the reservoir layer through the solid-state electrolyte layer, and wherein the first region of the oxide semiconductor layer is next to the gate electrode layer through the gate dielectric layer.

7. The semiconductor device of claim 2, further comprising:
a source electrode layer adjacent to a first side of the gate electrode layer and be electrically connected to a first portion of the oxide semiconductor layer; and
a drain electrode layer adjacent to a second side of the gate electrode layer and be electrically connected to a second portion of the oxide semiconductor layer.

8. The semiconductor device of claim 7,
wherein when a relatively low voltage is applied to the source electrode layer compared to a voltage applied to the gate electrode layer, the oxygen ions migrate from the reservoir layer to a second region of the oxide semiconductor layer through the solid-state electrolyte layer, and wherein the second region of the oxide semiconductor layer is next to the source electrode layer, and
wherein when a relatively high voltage is applied to the source electrode layer compared to a voltage applied to the gate electrode layer, the oxygen ions migrate from a second region of the oxide semiconductor layer to the reservoir layer through the solid-state electrolyte layer, and wherein the second region of the oxide semiconductor layer is next to the source electrode layer.

9. The semiconductor device of claim 7, wherein when a relatively low voltage is applied to the drain electrode layer compared to a voltage applied to the gate electrode layer, the oxygen ions migrate from the reservoir layer to a third region of the oxide semiconductor layer through the solid-state electrolyte layer, and wherein the third region of the oxide semiconductor layer is next to the drain electrode layer, and
wherein when a relatively high voltage is applied to the drain electrode layer compared to a voltage applied to the gate electrode layer, the oxygen ions migrate from a third region of the oxide semiconductor layer to the reservoir layer through the solid-state electrolyte layer, and wherein the third region of the oxide semiconductor layer is next to the drain electrode layer.

10. The semiconductor device of claim 1, wherein the reservoir layer contains oxygen in a content that satisfies a stoichiometric ratio or exceeds the stoichiometric ratio.

11. The semiconductor device of claim 1,
wherein the reservoir layer includes at least one of titanium oxide, tungsten oxide, lanthanum strontium manganese oxide, or ruthenium oxide, and
wherein the solid-state electrolyte layer includes at least one of yttria-stabilized zirconia, gadolinium oxide, or silicon oxide.

12. The semiconductor device of claim 1,
wherein the reservoir layer is electrically conductive, and
wherein the solid-state electrolyte layer is electrically insulating.

13. The semiconductor device of claim 1, wherein:
the reservoir layer is configured to supply or receive hydrogen ions, and
the solid-state electrolyte layer is configured to migrate the hydrogen ions from or to the reservoir layer.

14. The semiconductor device of claim 13, wherein by applying a voltage to the control electrode layer, the hydrogen ions migrate from the reservoir layer to the oxide semiconductor layer through the solid-state electrolyte layer, or migrate from the oxide semiconductor layer to the reservoir layer through the solid-state electrolyte layer.

15. The semiconductor device of claim 14,
wherein the gate electrode layer, the gate dielectric layer, and the oxide semiconductor layer form a transistor,
when the hydrogen ions migrate from the reservoir layer to the oxide semiconductor layer, a threshold voltage of the transistor decreases, and
when the hydrogen ions migrate from the oxide semiconductor layer to the reservoir layer, a threshold voltage of the transistor increases.

16. The semiconductor device of claim 1, wherein the reservoir layer contains a noble metal-containing material.

17. The semiconductor device of claim 1,
wherein the reservoir layer includes at least one of palladium, platinum, ruthenium, or ruthenium oxide, and
wherein the solid-state electrolyte layer includes yttria-stabilized zirconia, gadolinium oxide, silicon oxide, or phosphosilicate glass.

18. The semiconductor device of claim 1, further comprising:
a source electrode layer inside of the oxide semiconductor layer to be adjacent to a first side of the gate electrode layer; and
a drain electrode layer inside of the oxide semiconductor layer to be adjacent to a second side of the gate electrode layer.

19. The semiconductor device of claim 18, wherein the oxide semiconductor layer is in contact with a portion of a side wall of the source electrode layer and a portion of a side wall of the drain electrode layer.

20. The semiconductor device of claim 18, wherein the oxide semiconductor layer extends between the oxide semiconductor layer and the source electrode layer and between the oxide semiconductor layer and the drain electrode layer.
